(19) United States
(12) Patent Application Publication
(10) Pub. No.: US 2015/0372079 A1
(43) Pub. Date: Dec. 24, 2015

(54) NON-VOLATILE SEMICONDUCTOR MEMORY DEVICE AND METHOD OF MANUFACTURING NON-VOLATILE SEMICONDUCTOR MEMORY DEVICE

(71) Applicant: KABUSHIKI KAISHA TOSHIBA, Tokyo (JP)

(72) Inventors: Hiroaki NAITO, Yokkaichi Mie (JP); Tatsuya FUKUMURA, Yokkaichi Mie (JP)

(21) Appl. No.: 14/624,379

(22) Filed: Feb. 17, 2015

Related U.S. Application Data
(60) Provisional application No. 62/014,159, filed on Jun. 19, 2014.

(51) Int. Cl. H01L 29/06; H01L 29/49; H01L 29/423; H01L 27/115

(52) U.S. Cl. CPC H01L 29/0649; H01L 27/11568; H01L 27/11575; H01L 29/4941; H01L 29/42376

(57) ABSTRACT

According to an embodiment, a non-volatile semiconductor memory device includes plural gate electrodes in which a first insulating film, a charge storage layer, a second insulating film, and a control gate electrode layer are sequentially stacked on a semiconductor substrate, in which the control gate electrode layer includes a polysilicon layer that is formed on the second insulating film and a metal layer that is formed on the polysilicon layer, and a portion of the metal layer having the maximum width dimension is positioned above a lower end portion of the metal layer.

### FIELD

Embodiments described herein relate generally to a non-volatile semiconductor memory device and a method of manufacturing a non-volatile semiconductor memory device.

### BACKGROUND

As non-volatile semiconductor memory devices have become highly integrated, the half pitch of a memory cell transistor has decreased to nanometer size. Due to this decrease in the half-pitch, the distance between word-lines WL is extremely reduced. Therefore, there is a problem in that the breakdown voltage between word lines WL is reduced.

It has been found from an experiment that the breakdown voltage between word lines WL has a strong correlation with the distance between the bottom of a metal electrode portions of the word lines WL and the bottom of another metal electrode portion adjacent thereto. The cross-sectional shape of a metal electrode portion of a word line WL has a trapezoidal shape in which the bottom has a maximum width. Therefore, it is considered that leakage current is likely to be generated due to concentration of an electric field at the corner of the bottom of the metal electrode portion and the narrow width of the air gap near the bottom of the metal electrode portion.

### BRIEF DESCRIPTION OF THE DRAWINGS

FIG. 1 is an example of a diagram schematically illustrating an electrical configuration of a memory block of a NAND flash memory device according to a first embodiment.

FIG. 2 is an example of a plan view schematically illustrating a layout pattern of a part of a memory cell region.

FIG. 3 is an example of a vertical cross-sectional view schematically illustrating a structure of the memory cell region.

FIGS. 4 to 10 are examples of vertical cross-sectional views illustrating intermediate processes of manufacturing processes according to the first embodiment.

FIGS. 11 to 16 are examples of vertical cross-sectional views illustrating intermediate processes of manufacturing processes according to a second embodiment.

FIGS. 17 to 19 are examples of vertical cross-sectional views illustrating intermediate processes of manufacturing processes according to a third embodiment.

FIGS. 20 to 22 are examples of vertical cross-sectional views illustrating intermediate processes of manufacturing processes according to a fourth embodiment.

### DETAILED DESCRIPTION

Hereinafter, embodiments will be described with reference to the drawings. In each embodiment, substantially the same components are represented by the same reference numerals, and the description thereof will not be repeated. However, the drawings are schematic, and a relationship between thicknesses and planar dimensions, ratios of the thicknesses of each layer, and the like are different from those of the actual devices.

### First Embodiment

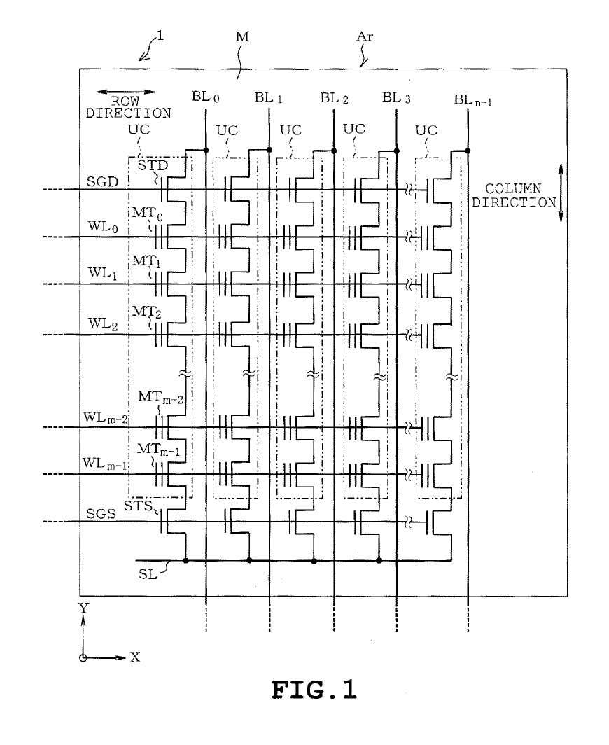

Hereinafter, in the first embodiment, for example, a NAND flash memory device which is used as a non-volatile semiconductor memory device will be described with reference to FIGS. 1 to 10. In the following description, an XYZ rectangular coordinate system is used for convenience of description. In this coordinate system, the two directions which are parallel to a surface of the semiconductor substrate and are perpendicular to each other are set as X and Y directions, a direction in which word lines WL extend is set as the X direction, and a direction which is perpendicular to the X direction and in which bit lines BL extend is set as the Y direction. A direction which is perpendicular to both the X direction and the Y direction is set as a Z direction.

FIG. 1 is an example of a diagram schematically illustrating an electrical configuration of a memory cell block of the NAND flash memory device. As illustrated in FIG. 1, the NAND flash memory device 1 includes a memory cell array Ar in which plural memory cells are disposed in a matrix.

In the memory cell array Ar inside a memory cell region M, plural unit memory cells UC are disposed. In the unit memory cells UC, select gate transistors STD are provided on a connection side to bit lines BL₀ to BLₙ₋₁, and select gate transistors STS are provided on a source line SL side. m (for example, m=2^{k}) memory cell transistors MT₀ to MTₘ₋₁ are connected in series between the select gate transistors STD and STS.

The plural unit memory cells UC form a memory cell block, and plural memory cell blocks form the memory cell array Ar. That is, in one block, the unit memory cells UC are disposed in parallel in n rows in a row direction (in FIG. 1, a horizontal direction, the X direction). In the memory cell array Ar, plural blocks are disposed in a column direction (in FIG. 1, a vertical direction, the Y direction). In order to simplify the description, one block is illustrated in FIG. 1.

A control line SGD is connected to gates of the select gate transistors STD. Word line WLₘ₋₁ is connected to control gates of m-th memory cell transistors MTₘ₋₁ which are connected to the bit lines BL₀ to BLₙ₋₁. Word line WL₂ is connected to control gates of third memory cell transistors MT₂ which are connected to the bit lines BL₀ to BLₙ₋₁. Word line WL₁ is connected to control gates of second memory cell transistors MT₁ which are connected to the bit lines BL₀ to BLₙ₋₁. Word line WL₀ is connected to the control gates of the first memory cell transistors MT₀ which are connected to the bit lines BL₀ to BLₙ₋₁. A control line SGS is connected to the gates of the select gate transistors STS which are connected to a source line SL. The control line SGD, the word lines WL₀ to WLₘ₋₁, the control line SGS, and the source line SL intersect with the bit lines BL₀ to BLₙ₋₁, respectively. The bit lines BL₀ to BLₙ₋₁ are connected to a sense amplifier (not illustrated).

The gate electrodes of the select gate transistors STD of the plural unit memory cells UC disposed in the row direction are electrically connected through the control line SGD. Likewise, the gate electrodes of the select gate transistors STS of the plural unit memory cells UC disposed in the row direction are electrically connected through the control line SGS. Sources of the select gate transistors STS are commonly connected to the source line SL. Gate electrodes of the memory cell transistors MT₀ to MTₘ₋₁ of the plural unit memory cells UC disposed in the row direction are electrically connected through the word lines WL₀ to WLₘ₋₁, respectively.

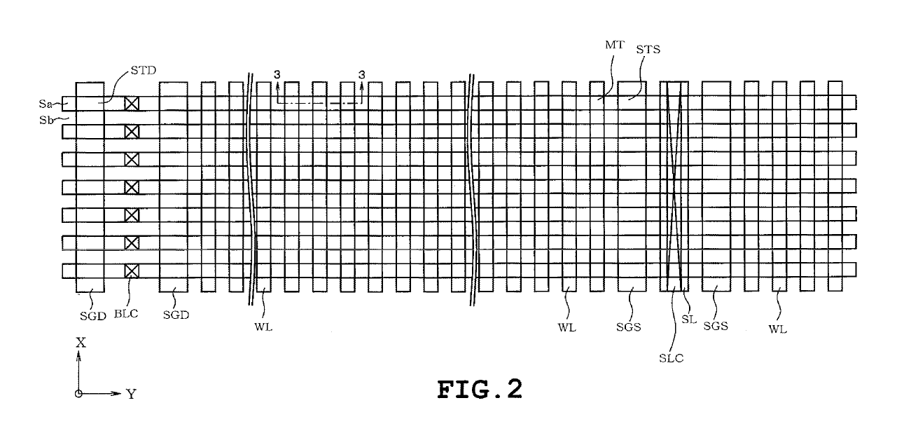

FIG. 2 is an example of a plan view schematically illustrating a layout pattern of a part of the memory cell region M. Hereinafter, the word lines WL₀ to WLₘ₋₁ will also be referred to as “word lines WL”, and the memory cell transistors MT₀ to MTₘ₋₁ will also be referred to as “memory cell transistors MT”.

In FIG. 2, the source line SL, the control line SGS, the word lines WL, and the control line SGD are spaced one another in the Y direction of the drawing (Column Direction in FIG. 1) and extend and are disposed in parallel to one another in the X direction of the drawing (Row Direction in FIG. 1).

Element isolation regions Sb are formed to extend in the Y direction of the figure. The element isolation regions Sb have a STI (shallow trench isolation) structure in which an insulating film is embedded into a trench. The plural element isolation regions Sb are formed at predetermined intervals in the X direction. Plural element regions Sa, which are formed to extend along the Y direction, are formed on a surface part of a silicon substrate 2 to be separated from each other in the X direction by the element isolation regions Sb. That is, the element isolation regions Sb are provided between the element regions Sa. In the semiconductor substrate, the plural element regions Sa are isolated by the element isolation regions Sb. The bit lines BL (not illustrated) are spaced from one another in the X direction at predetermined intervals so as to be positioned over the element regions Sa, and are disposed parallel to one another and extend in the Y direction, and are connected to the element regions Sa through bit line contacts BLC.

The word lines WL are formed to extend along a direction (X direction in FIG. 2) perpendicular to the element regions Sa. The plural word lines WL are formed at predetermined intervals in the Y direction of the drawing. The memory cell transistors MT are disposed at crossing locations of the word lines WL and the element regions Sa. The plural memory cell transistors MT adjacent to one another in the Y direction form a part of NAND strings (memory cell strings).

The select gate transistors STS and STD are disposed at crossing locations of the control lines SGS and SGD and the element regions Sa. The select gate transistors STS and STD are provided adjacent to each other at opposed sides, in the Y-direction, of the memory cell transistors MT (memory cells MG1) which are positioned at end portions of the NAND strings.

Plural select gate transistors STS on the source line SL side are provided in the X direction, and the gate electrodes of the plural select gate transistors STS are electrically connected through the control line SGS. The gate electrodes SG of the select gate transistors STS are formed at crossing points of the control line SGS and the element regions Sa. Source line contacts SLC are provided at crossing points of the source line SL and the bit lines BL.

The plural select gate transistors STD are provided in the X direction of the drawing, and the gate electrodes SG of the select gate transistors STD are electrically connected through the control line SGD. The select gate transistors STD are formed at crossing points of the control line SGD and the element regions Sa. The bit line contacts BLC are formed on the respective element regions Sa between adjacent select gate transistors STD.

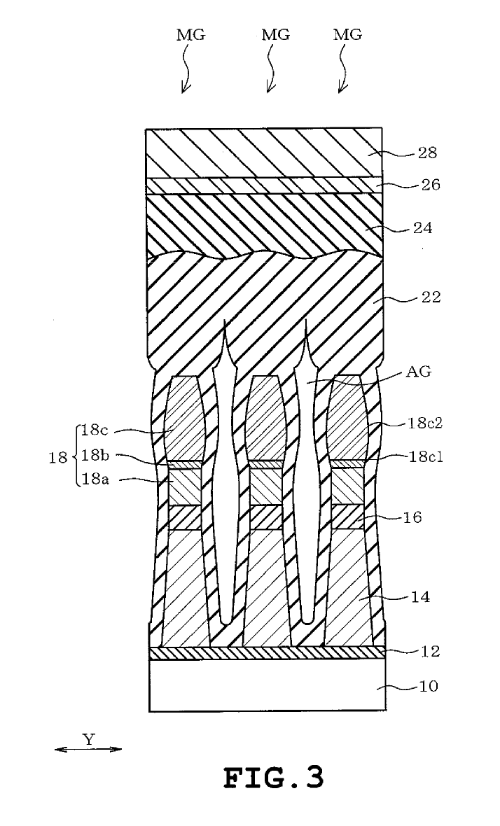

In addition, FIG. 3 is an example of a diagram schematically illustrating a cross-sectional structure of a portion taken along line 3-3 of FIG. 2. FIG. 3 illustrates a cross-sectional structure of a memory cell region of the NAND flash memory device according to the embodiment.

In FIG. 3, gate electrodes MG of plural memory cell transistors are provided on a semiconductor substrate 10. As the semiconductor substrate 10, a silicon substrate whose conductivity type is, for example, p type may be used. A gate insulating film (first insulating film) 12 is formed on the semiconductor substrate 10. As the gate insulating film 12, a silicon oxide film which is formed by, for example, thermal oxidation of the semiconductor substrate 10 (silicon substrate) may be used.

In the gate electrode MG, a charge storage layer 14, an inter-electrode insulating film 16, a control electrode 18 are stacked and formed on the gate insulating film 12. The charge storage layer 14 is formed of, for example, polysilicon (first polysilicon film 14) into which a dopant is introduced. As the dopant, for example, phosphorus or boron may be used.

As the inter-electrode insulating film (second insulating film) 16, for example, an ONO (Oxide Nitride Oxide) film which is a stacked film of a silicon oxide film/a silicon nitride film/a silicon oxide film or a structure in which polysilicon and a trapping layer such as HfO are stacked may be used.

The control electrode (control gate electrode layer) 18 is formed of a stacked film in which, for example, polysilicon (second polysilicon film 18a) into which a dopant is introduced, and a barrier metal film 18b, and a metal film 18c are sequentially stacked. As the dopant introduced into the second polysilicon film 18a, for example, phosphorus or boron may be used. As the barrier metal film 18b, tungsten nitride (WN) which is formed using, for example, a sputtering method may be used. As the metal film 18c, tungsten (W) which is formed using, for example, a sputtering method may be used. The barrier metal film 18b and the metal film 18c forma metal layer. The barrier metal film 18b is used to prevent a silicide reaction between polysilicon which forms the second polysilicon film 18a and tungsten which forms the metal film 18c.

Here, the width dimension in the horizontal direction (Y direction) of the barrier metal film 18b and the width dimension in the horizontal direction (Y direction) of a lower end portion (bottom) 18c1 of the metal film 18c are configured to be smaller than the width dimension in the horizontal direction (Y direction) of a maximum width portion 18c2 positioned at the center of the metal film 18c. Further, the side surface of a lower half portion of the metal film 18c and a side surface of the barrier metal film 18b have a round shape. As a result, the concentration of the electric field at a corner portion of the lower end portion (bottom) of the metal film 18c (and the barrier metal film 18b) may be reduced, and distance between the lower end portions (bottoms) of the adjacent metal films 18c (and the adjacent barrier metal films 18b) may increase.

In addition, an inter-electrode insulating film 16 is provided between the charge storage layer 14 and the control electrode 18. The charge storage layer 14 and the control electrode 18 are insulated from each other by the inter-electrode insulating film 16.

There are spaces between the respective plural gate electrodes MG, and an insulating film (third insulating film) 22 is provided so as to bridge over regions above the plural gate electrodes MG. In this way, the insulating film 22 is provided to cover the regions above the gaps, and thus the gaps between the gate electrodes MG form air gaps AG. As the insulating film 22, a silicon oxide film which is formed using, for example, a plasma CVD method may be used. The insulating film 22 is formed under conditions where coating properties are poor and thus does not embed into the inside of the air gaps AG. The insulating film 22 may be formed to be thin at the side surfaces of the gate electrodes MG positioned inside the air gaps AG. Due to the air gaps AG, the parasitic capacitance between the gate electrodes MG is reduced.

A first interlayer dielectric 24, a stop film 26, and a second interlayer dielectric 28 are provided on the insulating film 22. As the first interlayer dielectric 24 and the second interlayer dielectric 28, a silicon oxide film which is formed using, for example, a CVD method with TEOS (Tetraethyl orthosilicate) as source gas may be used. As the stopper film 26, a silicon nitride film which is formed using, for example, a CVD method may be used.

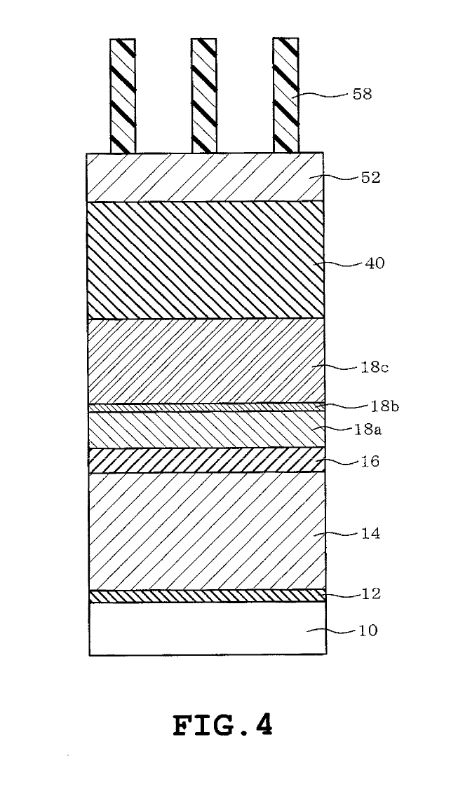

Next, a method of manufacturing a semiconductor device according to the embodiment will be described with reference to FIGS. 4 to 10. FIGS. 4 to 10 are examples of vertical cross-sectional views illustrating intermediate processes of manufacturing processes according to the embodiment, in which a cross-sectional structure of a portion taken along line 3-3 of FIG. 2 is schematically illustrated.

First, a resist 58 is formed in a state where, as illustrated in FIG. 4, the gate insulating film 12, the charge storage layer 14, the inter-electrode insulating film 16, the second polysilicon film 18a, the barrier metal film 18b, the metal film 18c, a mask insulating film 40, and a first mask film 52 are formed on the semiconductor substrate 10.

As the semiconductor substrate 10, a silicon substrate whose conductivity type is, for example, p type may be used. As the gate insulating film 12, a silicon oxide film which is formed by, for example, thermal oxidation of the semiconductor substrate 10 surface may be used. The charge storage layer (first polysilicon film) 14 may be formed of doped polysilicon using, for example, a CVD (Chemical Vapor Deposition) method and introducing, for example, phosphorus or boron into the polysilicon as a dopant. As the inter-electrode insulating film 16, for example, an ONO film may be used. The ONO film may be formed by sequentially forming a silicon oxide film/a silicon nitride film/a silicon oxide film using, for example, a CVD method. In the inter-electrode insulating film 16, openings are formed at portions where select gates SG are to be later formed.

The second polysilicon film 18a may be formed of doped polysilicon using, for example, a CVD method and introducing, for example, phosphorus or boron into the polysilicon as a dopant. As the barrier metal film 18b, tungsten nitride (WN) may be formed using, for example, a sputtering method. As the metal film 18c, tungsten (W) may be formed using, for example, a sputtering method. As the mask insulating film 40, a silicon oxide film which is formed using, for example, a CVD method may be used. As the first mask film 52, an amorphous silicon film which is formed using, for example, a CVD method may be used. The resist 58 may be formed, for example, by coating on the semiconductor substrate 10 using a coating method to form a resist having a predetermined thickness and patterning the resist using a lithography method.

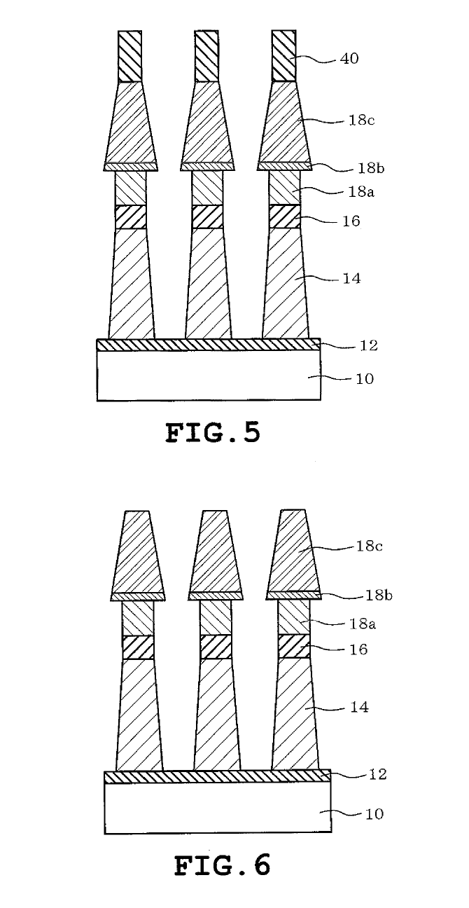

Next, as illustrated in FIG. 5, using the resist 58 as a mask, the first mask film 52, the mask insulating film 40, the metal film 18c, the barrier metal film 18b, the second polysilicon film 18a, the inter-electrode insulating film 16, and the charge storage layer 14 are sequentially removed by etching using a RIE (Reactive Ion Etching) method under anisotropic conditions. Due to this etching, the gate electrodes MG are formed. Etching is stopped at the gate insulating film 12. Due to the above-described etching, the cross-sectional shape of the metal film 18c and the barrier metal film 18b of the gate electrode MG has a trapezoidal shape in which the width dimension increases downward.

Next, as illustrated in FIG. 6, the mask insulating film is removed by etching using, for example, a diluted hydrofluoric acid solution.

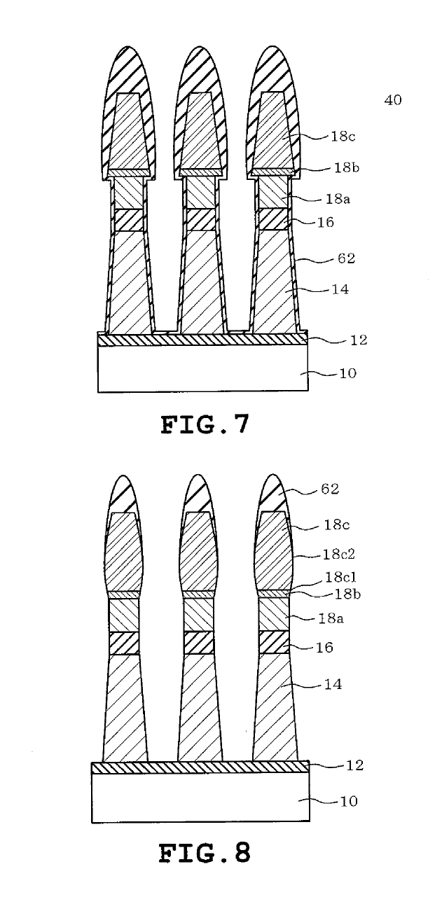

Next, as illustrated in FIG. 7, a cover insulating film 62 is formed on the side surfaces and the upper surface of the gate electrode MG using, for example, a plasma CVD method. As the cover insulating film 62, for example, a silicon oxide film may be formed.

Next, as illustrated in FIG. 8, the cover insulating film 62 is etched using, for example, a diluted hydrofluoric acid (DHF) solution. Due to this etching, the portion of the cover insulating film 62 which is positioned below the lower half portion of the metal film 18c of the gate electrode MG is removed, and the side surfaces of the lower half portion of the metal film 18c and a side surface of the barrier metal film 18b are rounded by etching. As a result, the width dimension in the horizontal direction (Y direction) of the barrier metal film 18b and the width dimension in the horizontal direction (Y direction) of the lower end portion (bottom) 18c1 of the metal film 18c are decreased to be smaller than the width dimension in the horizontal direction (Y direction) of the maximum width portion 18c2 positioned at the center of the metal film 18c.

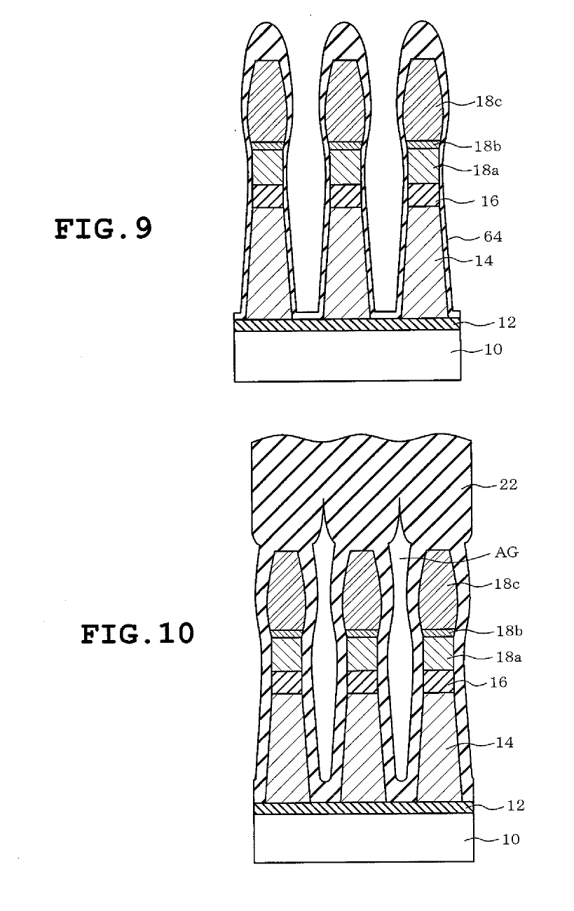

Next, as illustrated in FIG. 9, a side wall insulating film 64 is formed using, for example, a LTO (low temperature oxide) method on the side surface of the gate electrode MG and the side surface and the top surface of the cover insulating film 62. As this side wall insulating film 64, for example, a silicon oxide film (low temperature oxide film) may be formed.

Next, as illustrated in FIG. 10, the insulating film 22 is formed over the gate electrodes MG (side wall insulating film 64). As the insulating film 22, a silicon oxide film which is formed using, for example, a plasma CVD method under conditions where coating properties are poor may be used. As a result, the air gaps AG may be formed. In this case, positions of upper ends of the air gaps AG are higher than positions of upper ends of the metal films 18c of the gate electrodes MG.

Next, as illustrated in FIG. 3, the first interlayer dielectric 24, the stopper film 26, and the second interlayer dielectric 28 are sequentially formed on the insulating film 22. As the first interlayer dielectric 24 and the second interlayer dielectric 28, a silicon oxide film which is formed using, for example, a CVD method with TEOS as source gas may be used. As the stopper film 26, a silicon nitride film which is formed using, for example, a CVD method may be used. Next, wiring and the like (not illustrated) are formed using a well-known technique. Through the above-described processes, the semiconductor device according to the embodiment may be manufactured.

As described above, in the embodiment, the control electrode 18 (control gate electrode layer) includes: the polysilicon layer 18a that is formed on the inter-electrode insulating film 16 (second insulating film); and the metal layer, that is, the barrier metal film 18b and the metal film 18c that are formed on the polysilicon layer 18a, in which the portion (the maximum width portion 18c2 positioned at the center of the metal film 18c) of the metal layer having the maximum width dimension is configured to be positioned above the lower end portion (the barrier metal film 18b and the lower end portion (bottom) 18c1 of the metal film 18c) of the metal layer. With this configuration, concentration of an electric field on a corner portion of the lower end portion (bottom) of the metal film 18c (and the barrier metal film 18b) may be reduced, and the distance between the lower end portions (bottoms) of the adjacent metal films 18c (and the adjacent barrier metal films 18b) may increase. As a result, the breakdown voltage between the word lines WL may be improved. Further, in the embodiment, the side surface of the barrier metal film 18b and the side surface of the lower end portion of the metal film 18c are formed in a round shape. Therefore, concentration of an electric field may be further reduced.

In addition, in the embodiment, the positions of the upper ends of the air gaps AG are higher than the positions of the upper ends of the metal films 18c of the gate electrodes MG. Therefore, the breakdown voltage between the gate electrodes MG of the memory cells may be improved.

### Second Embodiment

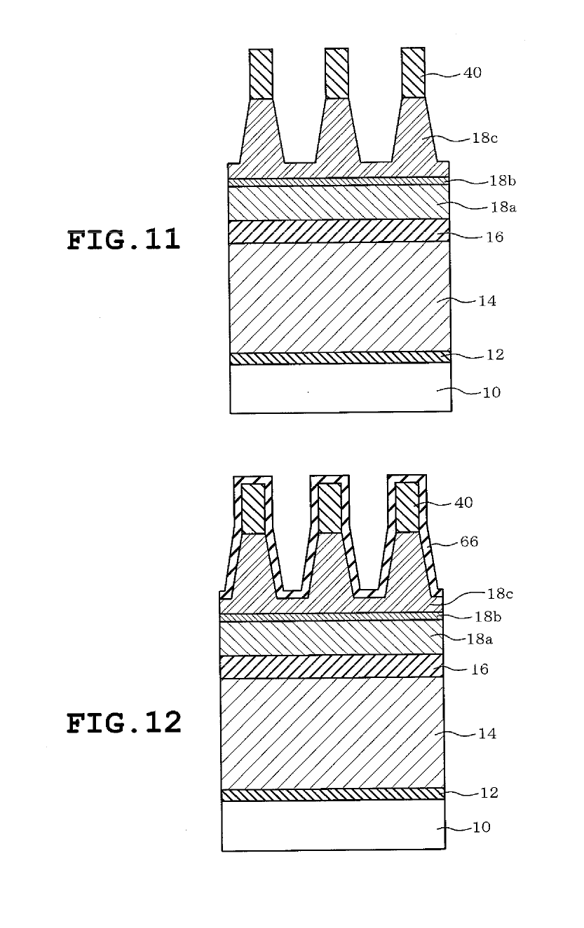

FIGS. 11 to 16 illustrate a second embodiment. The same components as those of the first embodiment are represented by the same reference numerals. In addition, a manufacturing method according to the second embodiment in which the side surface of the lower half portion of the metal film 18c and the side surface of the barrier metal film 18b in the gate electrode MG are rounded is different from that according to the first embodiment. Hereinafter, the manufacturing method according to the second embodiment will be described with reference to FIGS. 11 to 16.

The processes according to the second embodiment are the same as the first embodiment until the process of FIG. 4 of the first embodiment. Next, with the resist 58 (refer to FIG. 4) which is patterned as illustrated in FIG. 11 as a mask, the first mask film 52, the mask insulating film 40, and the metal film 18c are sequentially etched using a RIE method under anisotropic conditions. Etching progresses up to the mid part of the metal film 18c. At this time, an etched portion of the metal film 18c has a tapered shape in which the width dimension increases downward.

Next, as illustrated in FIG. 12, a spacer insulating film 66 is conformally formed on the metal film 18c and the mask insulating film 40 using, for example, a LTO method. As this spacer insulating film 66, a silicon oxide film having a thickness of, for example, about 3 nm may be used.

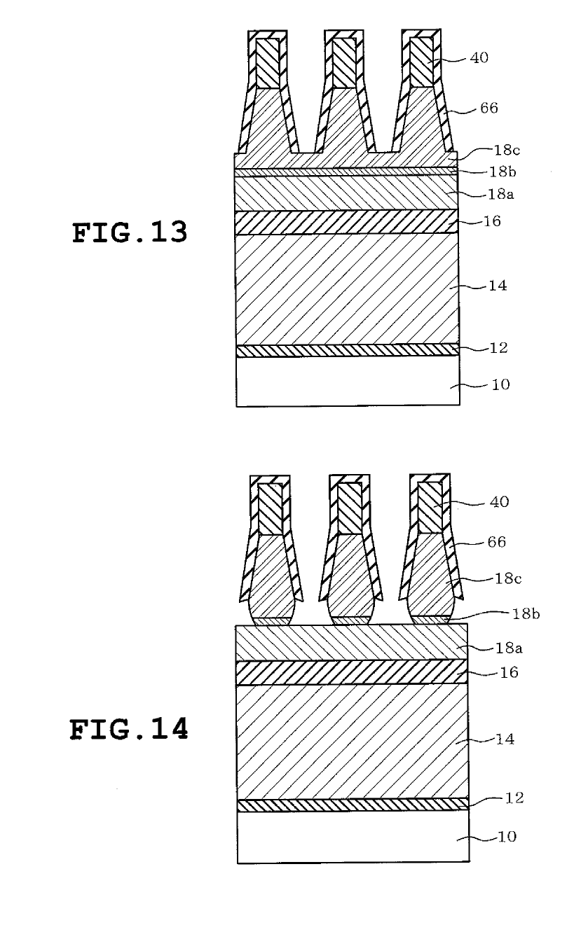

Next, as illustrated in FIG. 13, the spacer insulating film 66 is etched back using, for example, a RIE method. As a result, the spacer insulating film 66 remains only on the side surface of the metal film 18c and the side surface and the top surface of the mask insulating film 40.

Next, as illustrated in FIG. 14, with the spacer insulating film 66 as a mask, the metal film (tungsten) 18c and the barrier metal film (tungsten nitride) 18b are isotropically etched using, for example, a wet etching method. As a result, the top surface of the second polysilicon film 18a is exposed, the side surface of the bottom of the metal film 18c and the side surface of the barrier metal film 18b are rounded, and the side surface of the bottom of the metal film 18c and the side surface of the barrier metal film 18b have a reverse-tapered shape in which the width dimension decreases downward.

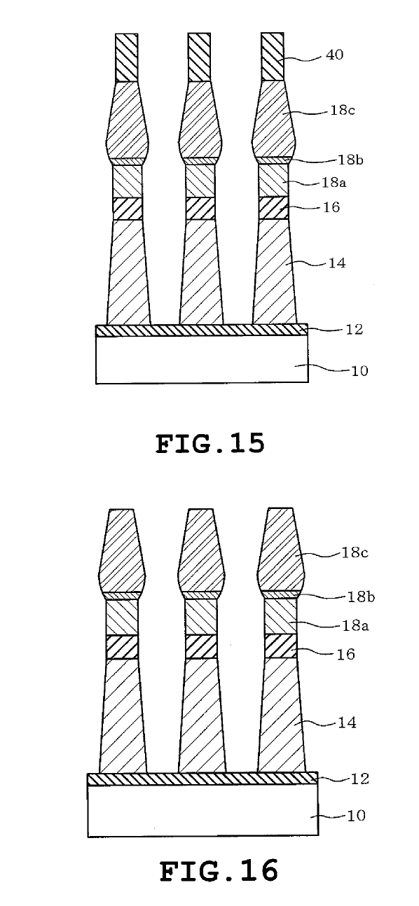

Next, as illustrated in FIG. 15, using the spacer insulating film 66 and the mask insulating film 40 as a mask, the second polysilicon film 18a, the inter-electrode insulating film 16, and the charge storage layer 14 are sequentially removed by etching using, for example, a RIE method.

Next, as illustrated in FIG. 16, the spacer insulating film 66 and the mask insulating film 40 are removed using, for example, a diluted hydrofluoric acid solution. Next, as illustrated in FIG. 10 of the first embodiment, the insulating film 22 is formed over the gate electrodes MG. As the insulating film 22, a silicon oxide film which is formed using, for example, a plasma CVD method under conditions where coating properties are poor may be used. As a result, the air gaps AG may be formed.

Configurations of the second embodiment other than the above-described configurations are the same as those of the first embodiment. Accordingly, in the second embodiment, substantially the same effects as those of the first embodiment may be obtained.

### Third Embodiment

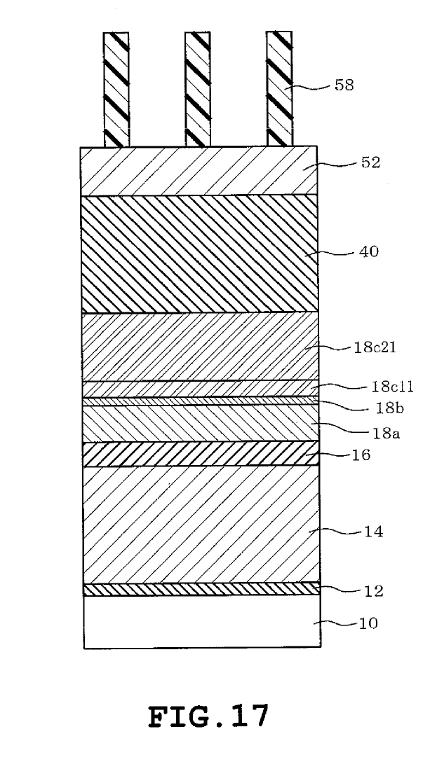

FIGS. 17 to 19 illustrate a third embodiment. The same components as those in the first embodiment are represented by the same reference numerals. In addition, a manufacturing method according to the third embodiment in which the side surface of the lower half portion of the metal film 18c and the side surface of the barrier metal film 18b in the gate electrode MG are rounded is different from those in the first embodiment and the second embodiment. Hereinafter, the manufacturing method of the third embodiment will be described with reference to FIGS. 17 to 19.

First, as illustrated in FIG. 17, the gate insulating film 12, the charge storage layer 14, the inter-electrode insulating film 16, the second polysilicon film 18a, the barrier metal film 18b, a first metal film 18c11, a second metal film 18c21, the mask insulating film 40, and the first mask film 52 are formed on the semiconductor substrate 10, and the resist 58 is formed thereon.

As the first metal film 18c11, a tungsten (W) film having a small grain size may be formed. As the second metal film 18c21, a tungsten (W) film having a larger grain size than that of the first metal film 18c11 may be formed.

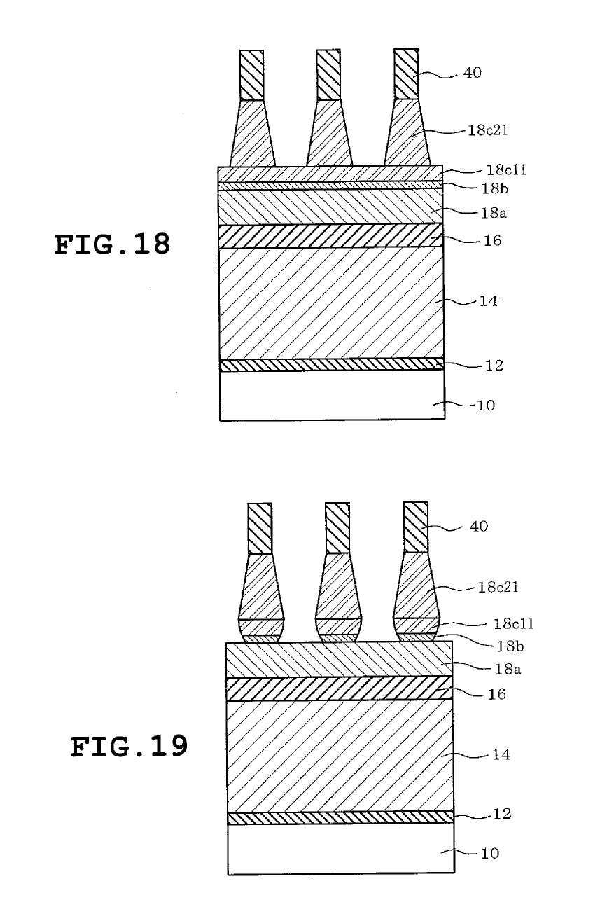

Next, with the resist 58 which is patterned as illustrated in FIG. 18 as a mask, the first mask film 52, the mask insulating film 40, and the second metal film 18c21 are sequentially etched using a RIE method under anisotropic conditions. As a result, the second metal film 18c21 has a tapered shape in which the width dimension increases downward.

Next, as illustrated in FIG. 19, the first metal film (tungsten) 18c11 is processed by isotropic etching. At this time, since the grain size of the first metal film 18c11 is smaller than that of the second metal film 18c21, the etching rate of the first metal film 18c11 is faster than that of the second metal film 18c21. The etching rate of the barrier metal film 18b is faster than that of the second metal film 18c21. As a result, the side surface of the bottom of the first metal film 18c11 and the side surface of the barrier metal film 18b have a reverse-tapered shape in which the width dimension decreases downward and have a round shape.

Next, as in the case of the first embodiment, using the mask insulating film 40 as a mask, the second polysilicon film 18a, the inter-electrode insulating film 16, and the charge storage layer 14 are etched using, for example, a RIE method. Next, after the mask insulating film 40 is removed, the insulating film 22 is formed over the gate electrodes MG as illustrated in FIG. 10 of the first embodiment. As the insulating film 22, a silicon oxide film which is formed using, for example, a plasma CVD method under conditions where coating properties are poor may be used. As a result, the air gaps AG may be formed.

Configurations of the third embodiment other than the above-described configurations are the same as those of the first embodiment. Accordingly, in the third embodiment, substantially the same effects as those of the first embodiment may be obtained.

### Fourth Embodiment

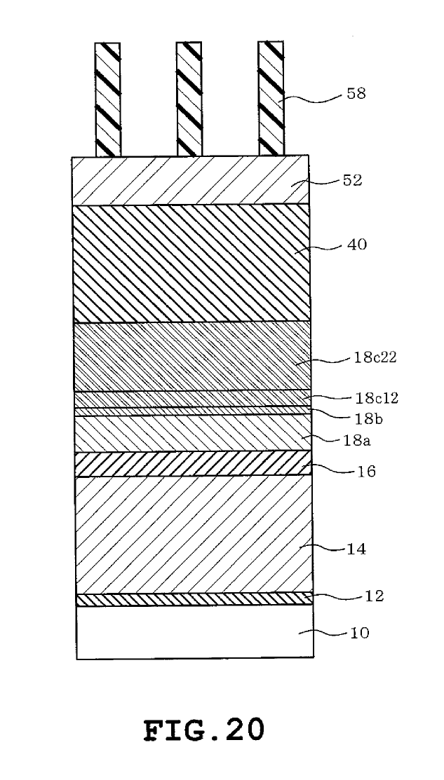

FIGS. 20 to 22 illustrate the fourth embodiment. The same components as those of the first embodiment are represented by the same reference numerals. In addition, a manufacturing method according to the fourth embodiment in which the side surface of the lower half portion of the metal film 18c and the side surface of the barrier metal film 18b in the gate electrode MG are rounded is different from those of the first embodiment, the second embodiment, and the third embodiment. Hereinafter, the manufacturing method according to the fourth embodiment will be described with reference to FIGS. 20 to 22.

First, as illustrated in FIG. 20, the gate insulating film 12, the charge storage layer 14, the inter-electrode insulating film 16, the second polysilicon film 18a, the barrier metal film 18b, a third metal film 18c12, a fourth metal film 18c22, the mask insulating film 40, and the first mask film 52 are formed on the semiconductor substrate 10, and the resist 58 is formed thereon.

As the third metal film 18c12, a tungsten (W) film in which a direction perpendicular to the semiconductor substrate 10 is crystal orientation 1 may be formed. As the fourth metal film 18c22, a tungsten (W) film in which a direction perpendicular to the semiconductor substrate 10 is crystal orientation 2 may be formed. Here, crystal orientation 1 is [001], and crystal orientation 2 is [111].

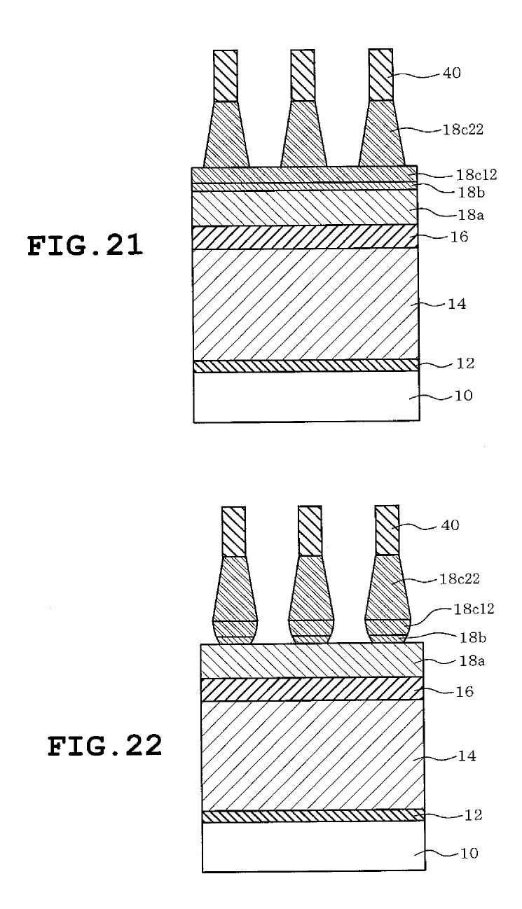

Next, with the resist 58 which is patterned as illustrated in FIG. 21 as a mask, the first mask film 52, the mask insulating film 40, and the fourth metal film 18c22 are sequentially etched using a RIE method under anisotropic conditions. As a result, the fourth metal film 18c22 has a tapered shape in which the width dimension increases downward.

Next, as illustrated in FIG. 22, the third metal film 18c12 is processed by isotropic etching. At this time, using a difference between the crystal orientations of tungsten, etching is performed under a condition where the etching rate of the third metal film 18c12 is faster than that of the fourth metal film 18c22. Next, etching is performed under a condition where the etching rate of the barrier metal film 18b is faster than that of the fourth metal film 18c22. As a result, the side surface of the bottom of the third metal film 18c12 and the side surface of the barrier metal film 18b have a reverse-tapered shape in which the width dimension decreases downward and have a round shape.

Next, as in the case of the first embodiment, with the mask insulating film 40 as a mask, the second polysilicon film 18a, the inter-electrode insulating film 16, and the charge storage layer 14 are etched using, for example, a RIE method. Next, after the mask insulating film 40 is removed, the insulating film 22 is formed over the gate electrodes MG as illustrated in FIG. 10 of the first embodiment. As the insulating film 22, a silicon oxide film which is formed using, for example, a plasma CVD method under conditions where coating properties are poor may be used. As a result, the air gaps AG may be formed.

Configurations of the fourth embodiment other than the above-described configurations are the same as those of the first embodiment. Accordingly, in the fourth embodiment, substantially the same effects as those of the first embodiment may be obtained.

### Other Embodiments

In addition to the above-described embodiments, the following configurations may be adopted.

In the above-described respective embodiments, the examples in which the ONO film is used as the inter-electrode insulating film 16 have been described. However, a NONON (nitride-oxide-nitride-oxide-nitride) film, an insulating film having high dielectric constant, or the like may be used.

The examples in which tungsten is used as the metal material forming the metal film 18c have been described. However, aluminum (Al) or titanium (Ti) may be used instead of tungsten.

In addition, in the above-described embodiments, the examples in which the NAND flash memory device is used have been described. However, a non-volatile semiconductor memory device such as a NOR flash memory device or a EEPROM may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a plurality of gate electrodes in which a first insulating film, a charge storage layer, a second insulating film, and a control gate electrode layer are sequentially stacked on a semiconductor substrate,
wherein the control gate electrode layer includes a polysilicon layer that is formed on the second insulating film and a metal layer that is formed on the polysilicon layer, and
a portion of the metal layer having the maximum width dimension is positioned above a lower end portion of the metal layer.

2. The device according to claim 1,
wherein a top surface of the metal layer is formed in a planar shape.

3. The device according to claim 1,
wherein a side surface of the lower end portion of the metal layer is formed in a round shape.

4. The device according to claim 1,
wherein the portion of the metal layer having the maximum width dimension is positioned below the center of the metal layer in a vertical direction.

5. The device according to claim 1,
wherein a side surface of a portion of the metal layer positioned above the portion having the maximum width dimension is formed in a planar shape.

6. The device according to claim 5,
wherein the portion of the metal layer positioned above the portion having the maximum width dimension has a tapered shape in which a width dimension increases downward.

7. The device according to claim 1,
wherein the maximum width dimension of the metal layer is larger than a width dimension of an upper end portion of the polysilicon layer.

8. The device according to claim 1,
wherein a width dimension of an upper end portion of the metal layer is smaller than the width dimension of the lower end portion of the metal layer.

9. The device according to claim 1,
wherein a third insulating film is embedded and an air gap is provided between the plurality of gate electrodes.

10. The device according to claim 9,
wherein a position of an upper end portion of the air gap is higher than a position of the upper end portion of the metal layer.

11. The device according to claim 10,
wherein a tip of the upper end portion of the air gap is sharp.

12. The device according to claim 1,
wherein the metal layer includes a barrier metal film that is formed on the polysilicon layer and a metal film that is formed on the barrier metal film.

13. The device according to claim 12,
wherein the barrier metal film is formed of tungsten nitride, and
the metal layer is formed of tungsten.

14. A method of manufacturing a non-volatile semiconductor memory device, the method comprising:
sequentially staking a first insulating film, a charge storage layer, a second insulating film, a polysilicon layer, and a metal layer on a semiconductor substrate;
processing the metal layer, the polysilicon layer, the second insulating film, and the charge storage layer to form a plurality of gate electrodes;
forming a fourth insulating film on a side surface and a top surface of the gate electrodes;
processing the fourth insulating film to expose a side surface of the charge storage layer of the gate electrode, a side surface of the second insulating film, a side surface of the polysilicon layer, and a side surface of the bottom of the metal layer;
processing the side surface of the bottom of the metal layer such that a portion of the metal layer having the maximum width dimension is positioned above a lower end portion of the metal layer; and
embedding a third insulating film between the gate electrodes.

15. The method according to claim 14,
wherein in processing the side surface of the bottom of the metal layer, a side surface of the lower end portion of the metal layer is formed in a round shape.

16. The method according to claim 14,
wherein in processing the side surface of the bottom of the metal layer, a portion of the metal layer having the maximum width dimension is positioned below the center of the metal layer in a vertical direction.

17. The method according to claim 14,
wherein the maximum width dimension of the metal layer is larger than a width dimension of an upper end portion of the polysilicon layer.

18. The method according to claim 14,
wherein a width dimension of an upper end portion of the metal layer is smaller than the width dimension of the lower end portion of the metal layer.

19. The method according to claim 14,
wherein an air gap is provided in the third insulating film between the plurality of gate electrodes.

20. The method according to claim 14,
wherein the metal layer includes a barrier metal film that is formed on the polysilicon layer and a metal film that is formed on the barrier metal film.
